(19) United States
(12) Patent Application Publication
(10) Pub. No.: US 2024/0178639 A1
(43) Pub. Date: May 30, 2024

(54) POWER DISTRIBUTION ROOM AND REFRIGERATION SYSTEM

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Shun WANG, Zhangjiakou City (CN)

(21) Appl. No.: 18/510,509

(22) Filed: Nov. 15, 2023

(30) Foreign Application Priority Data
Nov. 25, 2022 (CN) 202211493733.4

(51) Int. Cl. H02B 1/56; H05K 7/20

(52) U.S. Cl. CPC H02B 1/56; H05K 7/20354

(57) ABSTRACT

The present disclosure discloses a power distribution room and a refrigeration system. The power distribution room has an accommodation space internally provided with a first heat generating device. The first heat generating device has a vent, and a refrigeration device is connected to the vent of the first heat generating device. The refrigeration device includes a heat exchange apparatus and an induced draft apparatus, where the heat exchange apparatus is positioned between the induced draft apparatus and the vent. The induced draft apparatus is configured to generate an airflow flowing through the first heat generating device to generate hot air transmitted to the heat exchange apparatus, such that the heat exchange apparatus carries out heat exchange to convert the hot air into cold air and discharges the cold air into the accommodation space.

### CROSS REFERENCE TO RELATED APPLICATION

This application claims priority to Chinese Patent Application No. 202211493733.4, titled “POWER DISTRIBUTION ROOM AND REFRIGERATION SYSTEM” and filed to the China National Intellectual Property Administration on Nov. 25, 2022, the entire contents of which are incorporated herein by reference.

### TECHNICAL FIELD

The present disclosure relates to the field of refrigeration devices, and more particularly, to a power distribution room and a refrigeration system.

### BACKGROUND

At present, in most cases air conditioners in power distribution rooms of data centers are room air conditioners, whose refrigeration mode is relatively simple and airflow organization disordered, leading to a consequence that cold air supplied by the air conditioners cannot be sucked by heat generating devices unless the cold air is mixed with hot air.

To maintain proper inlet air temperature of transformers, uninterruptible power supply (UPS) and high-voltage direct current (HVDC) in the power distribution rooms, it is required to adjust the air conditioners in the existing power distribution rooms to a lower temperature, to supply cold air with low temperature, which however leads to higher power consumption and higher energy consumption of the air conditioners.

### SUMMARY

An objective of the present disclosure is to provide a power distribution room and a refrigeration system to reduce refrigeration energy consumption of the power distribution room.

To achieve the above objective, an aspect of the present disclosure provides a power distribution room having an accommodation space internally provided with a first heat generating device. The first heat generating device has a vent, and a refrigeration device is connected to the vent of the first heat generating device. The refrigeration device includes a heat exchange apparatus and an induced draft apparatus, where the heat exchange apparatus is positioned between the induced draft apparatus and the vent. The induced draft apparatus is configured to generate an airflow flowing through the first heat generating device to generate hot air transmitted to the heat exchange apparatus, such that the heat exchange apparatus carries out heat exchange to convert the hot air into cold air and discharges the cold air into the accommodation space.

To achieve the above objective, another aspect of the present disclosure also provides a refrigeration system, which at least includes a refrigeration device connected to the vent of the first heat generating device, where the first heat generating device and the refrigeration device are installed in the same enclosed space. The refrigeration device includes a heat exchange apparatus and an induced draft apparatus, where the heat exchange apparatus is positioned between the induced draft apparatus and the vent. The induced draft apparatus is configured to generate an airflow flowing through the first heat generating device to generate hot air transmitted to the heat exchange apparatus, such that the heat exchange apparatus carries out heat exchange to convert the hot air into cold air and discharges the cold air into the enclosed space.

As can be seen from the technical solutions provided by the present disclosure, the power distribution room has an accommodation space, a first heat generating device is installed in the accommodation space, and a heat exchange apparatus and an induced draft apparatus are connected to a vent of the first heat generating device, where the heat exchange apparatus is positioned between the induced draft apparatus and the vent. In this way, when the first heat generating device needs to be refrigerated, the induced draft apparatus and the heat exchange apparatus may be started, such that the induced draft apparatus generates an airflow flowing through the first heat generating device to generate hot air transmitted to the heat exchange apparatus, and the heat exchange apparatus carries out heat exchange to convert the hot air into cold air and discharges the cold air into the enclosed space. In this way, the hot air generated by the first heat generating device is limited between the heat exchange apparatus and the first heat generating device, such that other areas of the accommodation space are all in the cold air, to improve refrigeration airflow organization and enhance refrigeration energy efficiency, thereby reducing refrigeration energy consumption of the power distribution room. Moreover, the refrigeration device is installed at the vent on a side of the first heat generating device, compared to the existing mode where an inter-row air conditioner is arranged between two adjacent first heat generating devices, more heat generating devices may be arranged in the fixed accommodation space, thereby increasing number of devices arranged.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic top view of a power distribution room according to an embodiment of the present disclosure;

FIG. 2 is a schematic front view of the power distribution room according to an embodiment of the present disclosure;

FIG. 3 is a schematic diagram of connection between a first heat generating device and a refrigeration device according to an embodiment of the present disclosure; and

FIG. 4 is a schematic structural diagram of an induced draft apparatus according to an embodiment of the present disclosure.

### DETAILED DESCRIPTION

Detailed description of embodiments of the present disclosure will further be made below with reference to drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

At present, in most cases air conditioners in power distribution rooms of large data centers are room air conditioners, whose refrigeration mode is relatively simple and airflow organization disordered, leading to a consequence that cold air supplied by the air conditioners cannot be sucked by heat generating devices unless the cold air is mixed with hot air.

The power distribution rooms of the data centers mainly include transformers, low-voltage switchgear assemblies, uninterruptible power supply (UPS) or high-voltage DC power supply (HVDC) devices. As the most major heat generating devices, the UPS or HVDC devices generate heat accounting for more than 70% of total heat generated in the power distribution rooms. In contrast, heat generated by the transformers only accounts for about 20% of the total heat. In terms of heat dissipation modes, air is supplied from bottom and discharged from top of front and rear surfaces of the transformer, and generally air is supplied from front and discharged from rear or supplied from front and discharged from top for the UPS and HVDC, which may lead to disordered airflow organization in the power distribution room. Mixing of the cold air and the hot air may lead to higher energy consumption of the air conditioner.

To maintain proper inlet air temperature of the transformers, the UPS or HVDC devices in the power distribution rooms, it is required to adjust the air conditioners in the existing power distribution rooms to a lower temperature, to supply cold air with low temperature, which however leads to higher power consumption and higher energy consumption of the air conditioners.

Therefore, how to improve internal refrigeration structures of the existing power distribution rooms with respect to heating parts to reduce the refrigeration energy consumption has become an issue urgently to be solved in this field.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

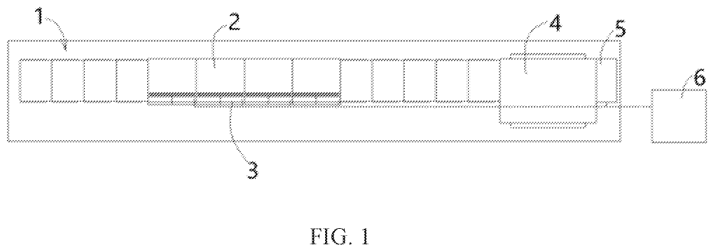

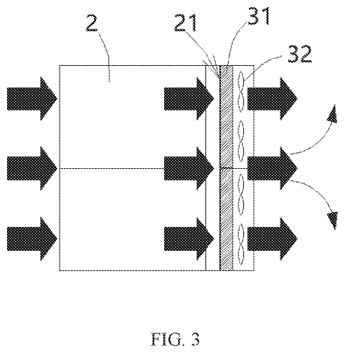

As shown in FIGS. 1 to 3, in one implementable embodiment, the power distribution room has an accommodation space 1 internally provided with a first heat generating device 2. The first heat generating device 2 has a vent 21 for communicating with external air. In practical applications, a heat generating device typically has a plurality of vents 21 to achieve communication with the external air to carry out heat exchange. It is worth mentioning that the “heat generating device” defined in the present disclosure refers to a device that generates heat in operation.

In this embodiment, a refrigeration device 3 is connected to the vent 21 of the first heat generating device 2. It should be pointed out that definition of “the refrigeration device 3 is connected to the vent 21 of the first heat generating device 2” does not mean that the refrigeration device 3 is connected to each vent 21 of the first heat generating device 2, but rather means the refrigeration device 3 is arranged on one of a plurality of vents 21 of the first heat generating device 2. Thus, air may be supplied from other vents 21 and may be discharged from this vent 21, thereby forming a refrigeration cycle. The above refrigeration device 3 may include a heat exchange apparatus 31 and an induced draft apparatus 32, where the heat exchange apparatus 31 is configured to carry out heat exchange to hot air flowing through it to refrigerate the hot air. The heat exchange apparatus 31 is positioned between the induced draft apparatus 32 and the vent 21. The induced draft apparatus 32 is configured to generate an airflow flowing through the first heat generating device 2 to generate the hot air transmitted to the heat exchange apparatus 31, such that the heat exchange apparatus 31 carries out heat exchange to convert the hot air into cold air and discharges the cold air into the accommodation space 1. In this way, the hot air generated by the first heat generating device 2 may be limited between the heat exchange apparatus 31 and the first heat generating device 2, such that the hot air flows through the heat exchange apparatus 31 for refrigeration, which can change airflow organization form, improve refrigeration energy efficiency, and reduce refrigeration energy consumption of the power distribution room. The cold air formed by refrigerating the hot air by the heat exchange apparatus 31 is discharged into the accommodation space 1, such that the accommodation space 1 is always in the cold air, which may also be used for refrigerating other devices with less heat generation.

Moreover, the refrigeration device 3 is installed at the vent 21 on a side of the first heat generating device 2, compared to the existing mode where an inter-row air conditioner is arranged between two adjacent first heat generating devices 2, more heat generating devices may be arranged in the accommodation space 1 with a constant volume, thereby increasing number of devices arranged.

Furthermore, both the induced draft apparatus 32 and the heat exchange apparatus 31 should cover the vent 21, such that the refrigeration efficiency of the heat exchange apparatus 31 on the hot air generated by the first heat generating device 2 may be improved.

In practical applications, the power distribution room being used in the data center is taken as an example. The power distribution room may be provided with transformers, low-voltage switchgear assemblies, uninterruptible power supply (UPS) or high-voltage DC power supply (HVDC) devices, etc. These devices may generate heat during operation, and thus may be defined as the heat generating devices in the present disclosure. In one embodiment, the UPS or HVDC device accounting for a larger proportion of heat generation may be selected as the first heat generating device 2, and the refrigeration device 3 is arranged at one of the vents of this first heat generating device 2 for refrigeration, thereby forming a refrigeration cycle. In another implementable embodiment, all the heat generating devices in the power distribution room may be selected the first heat generating device, that is, the above refrigeration device 3 is installed at the vent of each heat generating device.

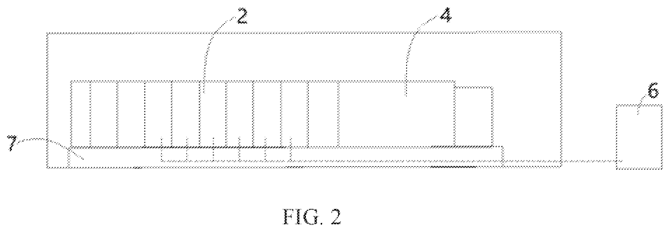

In an implementable embodiment, referring to FIGS. 1 and 2 again, a second heat generating device 4 and an inter-row air conditioner 5 may also be installed in the accommodation space 1. Heat generated by the second heat generating device 4 is smaller than heat generated by the first heat generating device 2. The inter-row air conditioner 5 is arranged on a side of the second heat generating device 4.

In this embodiment, the heat generating device with a lower heat generation may be refrigerated by the cold air in the accommodation space 1. However, to ensure the refrigeration effect, an inter-row air conditioner may also be installed in accommodation space 1, and inter-row air conditioner is arranged on a side of the second heat generating device 4 to assist the cold air in refrigeration to ensure the refrigeration effect.

In practical applications, in the power distribution room, the heat generated by the transformer only accounts for 20% of the total heat. Because of its lower heat generation, the transformer may be selected as the second heat generating device 4, and is placed in the cold air of the accommodation space 1, thus assisting the inter-row air conditioner in refrigeration.

In an implementable embodiment, after the heat exchange apparatus 31 absorbs the heat in the accommodation space 1, the heat needs to be transferred to outside of the power distribution room to dissipate the heat, thus forming a refrigeration cycle. Specifically, the power distribution room also includes an outdoor unit 6, which is installed on an outer side of the accommodation space 1. The heat exchange apparatus 31 and the inter-row air conditioner 5 are respectively communicated with the outdoor unit 6.

In practical applications, the above heat exchange apparatus 31 is an evaporator, and correspondingly, the outdoor unit 6 at least includes a condenser, a compressor, and an expansion valve connected in series with each other to form a refrigeration cycle. It should be particularly noted that reference may be made to the existing technologies for specific structures and connectivity relationships between the evaporator, the condenser, the compressor and the expansion valve, which are not to be described in detail here.

Connecting pipes between the outdoor unit 6 and the inter-row air conditioner 5 and the heat exchange apparatus 31 in the accommodation space are reasonably arranged. In an implementable embodiment, after being connected in parallel with the inter-row air conditioner 5, the heat exchange apparatus 31 is connected in series with the outdoor unit 6 to form a refrigeration cycle. In this way, number of the outdoor units 6 may be reduced, and number of the pipes may also be reduced, to facilitate installation and operation, reduce engineering workload, and reduce costs. Further, the accommodation space 1 is also internally provided with a bottom frame 7. The first heat generating device 2 and the second heat generating device 4 are connected to the bottom frame 7, such that a connecting pipe between the heat exchange apparatus 31 and the outdoor unit 6 may be embedded into the bottom frame 7, which can facilitate layout planning, avoid pipes being disordered, and improve aesthetic degree.

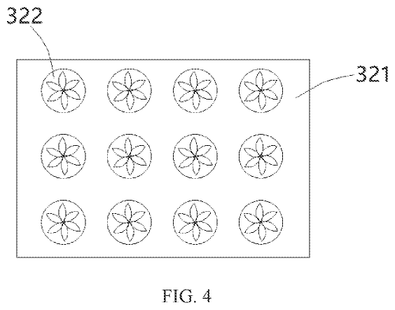

Specific structures of the induced draft apparatus 32 may be seen in FIG. 4. As shown in FIG. 4, in an implementable embodiment, the induced draft apparatus may at least include a frame 321 and a plurality of fan components 322. The frame 321 covers the vent 21; and the plurality of fan components 322 are installed on the frame 321, and the plurality of fan components 322 are arranged in a rectangular array. In this way, as the fan components 322 rotate, air in the corresponding first heat generating device 2 may be extracted and discharged to outside, thereby forming the airflow.

Based on the same inventive concept, the present disclosure also provides a refrigeration system, which at least includes a refrigeration device 3 connected to a vent 21 of a first heat generating device 2, where the first heat generating device 2 and the refrigeration device 3 are installed in the same enclosed space. The refrigeration device 3 includes a heat exchange apparatus 31 and an induced draft apparatus 32, where the heat exchange apparatus 31 is positioned between the induced draft apparatus 32 and the vent 21. The induced draft apparatus 32 is configured to generate an airflow flowing through the first heat generating device 2 to generate hot air transmitted to the heat exchange apparatus 31, such that the heat exchange apparatus 31 carries out heat exchange to convert the hot air into cold air and discharges the cold air into the enclosed space.

It should be noted that the above refrigeration system may be used in the power distribution room of the data center to refrigerate the heat generating device in the power distribution room. Of course, the refrigeration system may also be used in other environments where the heat generating device needs to be refrigerated, which is not specifically limited in the present disclosure. Reference may be made to the above contents for specific structures of the first heat generating device 2 and the refrigeration device 3, which are not to be described in detail here.

As can be seen from the technical solutions provided by the present disclosure, the power distribution room has an accommodation space, a first heat generating device is installed in the accommodation space, and a heat exchange apparatus and an induced draft apparatus are connected to a vent of the first heat generating device, where the heat exchange apparatus is positioned between the induced draft apparatus and the vent. In this way, when the first heat generating device needs to be refrigerated, the induced draft apparatus and the heat exchange apparatus may be started, such that the induced draft apparatus forms an airflow flowing through the first heat generating device to generate hot air transmitted to the heat exchange apparatus, and the heat exchange apparatus carries out heat exchange to convert the hot air into cold air and discharges the cold air into the enclosed space. In this way, the hot air generated by the first heat generating device is limited between the heat exchange apparatus and the first heat generating device, such that other areas of the accommodation space are all in the cold air, to improve refrigeration airflow organization, thereby reducing refrigeration energy consumption of the power distribution room. Moreover, the refrigeration device is installed at the vent on a side of the first heat generating device, compared to the existing mode where an inter-row air conditioner is arranged between two adjacent first heat generating devices, more heat generating devices may be arranged in the fixed accommodation space, thereby increasing number of devices arranged.

Furthermore, according to heat generation conditions of the devices in the power distribution room, the devices may be classified into the first heat generating device and the second heat generating device. In this way, according to actual refrigeration requirements, it may be selected whether the refrigeration devices are installed for refrigeration or the refrigeration mode of combining the cold air with the inter-row air conditioner is used, thereby reasonably distributing the refrigeration devices and reducing the refrigeration energy consumption.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A power distribution room having an accommodation space, wherein a first heat generating device is installed in the accommodation space;
the first heat generating device has a vent, and a refrigeration device is connected to the vent of the first heat generating device;
the refrigeration device comprises a heat exchange apparatus and an induced draft apparatus, the heat exchange apparatus being positioned between the induced draft apparatus and the vent; and
the induced draft apparatus is configured to generate an airflow flowing through the first heat generating device to generate hot air transmitted to the heat exchange apparatus, such that the heat exchange apparatus carries out heat exchange to convert the hot air into cold air and discharges the cold air into the accommodation space.

2. The power distribution room according to claim 1, wherein the accommodation space is further internally provided with a second heat generating device and an inter-row air conditioner;
heat generating capacity of the second heat generating device is smaller than heat generating capacity of the first heat generating device; and
the inter-row air conditioner is arranged on a side of the second heat generating device.

3. The power distribution room according to claim 2 further comprising an outdoor unit;
wherein the outdoor unit is installed on an outer side of the accommodation space; and
after being connected in parallel with the inter-row air conditioner, the heat exchange apparatus is connected in series with the outdoor unit to form a refrigeration cycle.

4. The power distribution room according to claim 3, wherein the accommodation space is further internally provided with a bottom frame; and
the first heat generating device and the second heat generating device are connected to the bottom frame, and a connecting pipe between the heat exchange apparatus and the outdoor unit is embedded into the bottom frame.

5. The power distribution room according to claim 4, wherein the heat exchange apparatus is an evaporator; and
correspondingly, the outdoor unit at least comprises a condenser, a compressor, and an expansion valve connected in series with each other.

6. The power distribution room according to claim 1, wherein the induced draft apparatus comprises a frame and a plurality of fan components;
the frame covers the vent; and
the plurality of fan components are installed on the frame, and the plurality of fan components are arranged in a rectangular array.

7. The power distribution room according to claim 2, wherein the first heat generating device is an uninterruptible power supply device and a high-voltage DC power supply device; and
the second heat generating device is a transformer device.

8. A refrigeration system at least comprising a refrigeration device connected to a vent of a first heat generating device, wherein the first heat generating device and the refrigeration device are installed in a same enclosed space;
the refrigeration device comprises a heat exchange apparatus and an induced draft apparatus, the heat exchange apparatus being positioned between the induced draft apparatus and the vent; and
the induced draft apparatus is configured to generate an airflow flowing through the first heat generating device to generate hot air transmitted to the heat exchange apparatus, such that the heat exchange apparatus carries out heat exchange to convert the hot air into cold air and discharges the cold air into the enclosed space.

9. The refrigeration system according to claim 8 further comprising an outdoor unit; wherein the outdoor unit is connected in series with the heat exchange apparatus to form a refrigeration cycle.

10. The refrigeration system according to claim 8, wherein the induced draft apparatus comprises a frame and a plurality of fan components;
the frame covers the vent; and
the plurality of fan components are installed on the frame, and the plurality of fan components are arranged in a rectangular array.

11. The refrigeration system according to claim 8, wherein the first heat generating device is an uninterruptible power supply device and a high-voltage DC power supply device.
